(19) United States
(12) Patent Application Publication
(10) Pub. No.: US 2025/0261303 A1
(43) Pub. Date: Aug. 14, 2025

(54) Hardware Tool for Connecting Devices of Various Interfaces

(71) Applicant: Google LLC, Mountain View, CA (US)

(72) Inventor: Patrick Michael Kiley, Las Vegas, NV (US)

(21) Appl. No.: 19/049,785

(22) Filed: Feb. 10, 2025

Related U.S. Application Data
(60) Provisional application No. 63/553,476, filed on Feb. 14, 2024.

(51) Int. Cl. H05K 1/02; H01R 12/72; H01R 13/66; H05K 1/18

(52) U.S. Cl. CPC H05K 1/0286; H01R 12/72; H01R 13/665; H05K 1/181

(57) ABSTRACT

The present disclosure provides for an example multi-protocol board assembly for hacking. The multi-protocol board assembly can include a universal serial bus (USB) to 4-serial channel processor chip. The multi-protocol board assembly can include eight light-emitting diode (LED) indicators. The multi-protocol board assembly can include an EEPROM communicatively connected to the USB to 4-serial channel process chip and the eight LED indicators. The multi-protocol board assembly can include a first 20-pin connector connected to a first side of the multi-protocol board assembly. The multi-protocol board assembly can include a second 20-pin connector connected to a second side of the multi-protocol board assembly wherein the first side of the multi-protocol board assembly is located orthogonal to the second side of the multi-protocol board assembly.

### PRIORITY CLAIM

The present application claims priority to and the benefit of U.S. Provisional Patent Application No. 63/553,476 having a filing date of Feb. 14, 2024. U.S. Provisional Patent Application No. 63/553,476 is hereby incorporated by reference in its entirety.

### FIELD

The present disclosure relates generally to hardware tools for connecting devices of various interfaces. Hardware tools for connecting devices of various interfaces can include multi-protocol board assemblies for use as a multi-port serial hacking tool.

### BACKGROUND

Existing hardware tools for connecting devices of various interfaces allow for connecting two serial channels simultaneously. Existing hardware tools may also include level-shifters to allow for connection of logic voltages. Such existing hardware tools can sometimes be used by engineers, researchers, information technology professionals, or other users to test the security or vulnerability of the products that they are building or using. In these cases, the hardware tools may be referred to as “hacking tools”.

### SUMMARY

Aspects and advantages of embodiments of the present disclosure will be set forth in part in the following description, or can be learned from the description, or can be learned through practice of the embodiments.

In one example aspect, the present disclosure provides for an example hardware tool for connecting devices of various interfaces. The example hardware tool can be a multi-protocol board assembly. The multi-protocol board assembly can include a universal serial bus (USB) to 4-serial channel processor chip. The multi-protocol board assembly can include eight light-emitting diode (LED) indicators. The multi-protocol board assembly can include an EEPROM communicatively connected to the USB to 4-serial channel process chip and the eight LED indicators. The multi-protocol board assembly can include a first 20-pin connector connected to a first side of the multi-protocol board assembly. The multi-protocol board assembly can include a second 20-pin connector connected to a second side of the multi-protocol board assembly. The first side of the multi-protocol board assembly can be located orthogonal to the second side of the multi-protocol board assembly.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, serve to explain the related principles.

### BRIEF DESCRIPTION OF THE DRAWINGS

Detailed discussion of embodiments directed to one of ordinary skill in the art is set forth in the specification, which refers to the appended figures, in which:

FIG. 1 depicts an example rendering of the multi-protocol board according to example aspects of the present disclosure;

FIG. 2 depicts an example rendering of the multi-protocol board according to example aspects of the present disclosure;

FIG. 3A depicts an example front of the multi-protocol board according to example aspects of the present disclosure;

FIG. 3B depicts an example front of the multi-protocol board according to example aspects of the present disclosure;

FIG. 4 depicts an example back of the multi-protocol board according to example aspects of the present disclosure;

FIG. 5 depicts an example multi-protocol board according to example aspects of the present disclosure;

FIG. 6 depicts an example front of the multi-protocol board according to example aspects of the present disclosure;

FIG. 7 depicts an example front of the multi-protocol board according to example aspects of the present disclosure; and

FIG. 8 depicts an example front of the multi-protocol board according to example aspects of the present disclosure.

Reference numerals that are repeated across plural figures are intended to identify the same features in various implementations.

### DETAILED DESCRIPTION

Generally, the present disclosure is related to an example multi-protocol board which can be used as a multi-port serial hacking tool. For example, the multi-protocol board may have four different ports which enable the multi-protocol board of the present disclosure to simultaneously connect to machine interfaces such as, for example, universal asynchronous receiver/transmitter (UART), joint test action group (JTAG), serial peripheral interface (SPI), and/or inter-integrated circuit (I2C). The four serial channel multi-protocol board of the present disclosure can connect to multiple serial ports simultaneously to facilitate communication between different hardware components, allowing for more efficient debugging and testing procedures. For instance, the tool can be used for facilitating man in the middle (MITM) attacks or other hardware hacking.

Existing multi-protocol boards provide for interfacing with two serial channels. In instances where additional interfaces need to be connected, multiple multi-protocol boards must be used. Connecting multiple two-serial channel multi-protocol boards can provide for challenges relating to debugging and determining whether issues are coming from the manner in which the multiple multi-protocol boards are connected or from the components which are connected via the serial channel ports. The present disclosure provides for an improved multi-protocol board that allows for connecting to four serial channel ports simultaneously, which can allow for increased efficiencies in system debugging.

The example multi-protocol board described in the present disclosure can be compatible with any serial console that can connect to a universal serial bus (USB) to serial port chip (e.g., 4-serial channel processor chip 102). For instance, this can include the FTDI (Future Technology Devices International) x23x series chips. The multi-protocol board can include one or more level shifters. The level shifters can be configured such that the multi-protocol board can connect to any logic voltage between 1.65V and 5.5V. This feature can be particularly useful in applications that require varying voltage levels. For example, it can be used in systems that operate at different voltage levels, allowing for seamless integration and interoperability between different components.

Additionally, in some implementations, the multi-protocol board can include a rotary switch that can be manipulated to select a voltage or allow for the shifter to match the voltage of a target. For instance, the rotary switch can have a first position associated with 1.8V, a second position associated with 3.3V, a third position associated with 5V, and a fourth position which allows the shifter to match the voltage of the target. The level shifter and varying voltages allows for compatibility between integrated circuits with different voltage requirements.

The multi-protocol board described herein can be designed to be compatible with several libraries that already support the FTDI x23x series of interfaces, including OpenOCD (On-Chip Debugger). This means that any serial console that can connect to an FTDI-based USB to serial port should be able to use this tool. For instance, it can be used with a variety of software tools and platforms, providing flexibility and versatility in its application.

In some implementations, the example multi-protocol board described herein can include two 20-pin bus connectors that are compatible with industry-standard 20-pin adapters. As one example, the 20-pin bus connectors can be pin-compatible with the 20-pin Segger J-link. This means that a number of adapters for the J-link should work directly with the proposed hardware tool. For example, this can allow for easy integration with existing hardware setups, reducing the need for additional adapters or connectors.

Additionally, the multi-protocol board can provide for separate TX and RX indicators for each of the four serial channels. For instance, the TX and RX indicators can include light-emitting diode (LED) indicator lights. The TX indicators provide for an indication of signals being transmitted and the RX indicators provide for an indication of signals being received. The RX and TX can be associated with digital signals being transmitted via the respective channels. The configuration of the multi-protocol board allows for connection between the USB to serial port chip (e.g., FTDI x23x series chip), the Electrically Erasable Programmable Read-Only Memory (EEPROM), and the shift register to provide for visual indication of the transmission of signals by the various serial channels. The indicator lights can aid in troubleshooting whether issues are stemming from hardware or software being used.

The LED indicators can receive signals that are broken into eight separate TX and RX signals. As the USB to serial port chip boots, it pulls identification data from the EEPROM. After this boot, the channels associated with EEPROM traditionally would not be utilized. The multi-protocol board of the present disclosure uses these channels to communicate with the serial register, serialize the data, and then break the data into the eight separate TX and RX signals. This provides for a more efficient use of existing computing resources instead of requiring additional channels to be provided within the multi-protocol board to obtain the same channels for communication relating to the signals being transmitted and received by the respective serial channels. For instance, the EEPROM can include an EEPROM Chip Select (EECS), EEPROM Clock (EECLK), and EEPROM Data (EEDATA) line. These lines can be physically connected via a conductive wire to the USB to serial port chip and the LED indicators.

When the multi-protocol board is connected to an external computing device, the computing device can determine the multi-protocol board has four serial ports. In some cases, three of the ports can be a serial port (e.g., UART) and one port can be a multi-purpose port (e.g., JTAG, SWD (Serial Wire Debug), I2C, SPI). UART defines a protocol for exchanging serial data between two devices. UART uses two wires between transmitter and receiver to transmit and receive in both directions. JTAG is an industry standard for verifying designs and testing printed circuit boards after manufacture. JTAG can be utilized for debugging and programming as well as testing printed circuit boards (PCBs) without physical access or function test development. JTAG provides for on-chip instrumentation in electronic design automation to work alongside digital simulation. SWD is a serial wire debug which is a modification of JTAG used for ARM programming. I2C is a synchronous, controller/target, single-ended serial communication bus. The I2C protocol allows for multiple peripheral chips (e.g., digital integrated circuits) to communicate with one or more controller chips. I2C are useful for short distance communications and only require two signal wires to exchange information. SPI is a standard for synchronous serial communication which is used primarily in embedded systems for short distance wired communication between integrated circuits. SPI is an interface bus often used to send data between microcontrollers and shift registers, sensors, or SD cards. Thus, the four serial ports can allow for multiple simultaneous connections and data transmissions, which can be useful in complex systems that require high levels of data processing and communication.

In some implementations, the multi-protocol board described herein can include a logic analyzer. For instance, the logic analyzer can include a 14-pin 2.54 mm (e.g., 0.1 inch) pitch connector used to attach the logic analyzer to the board. The logic analyzer can be connected via various means, such as a Dupont style jumper wires or another connector to interface with the TX and RX pins or respective serial channels.

Additionally, in some implementations, the multi-protocol board can include a 10-pin mini cortex connecter, an 8-pin SPI, and a 4-pin I2C connector. These connectors can be used to connect to a variety of devices and interfaces, providing flexibility in its application. For example, it can be used to connect to microcontrollers, memory devices, and other peripheral devices, allowing for a wide range of potential applications.

The present disclosure describes a versatile and flexible hardware hacking tool that can be used in a variety of applications. Its design features, such as its level-shifter, rotary switch, multi-port design, and compatibility with several libraries, make it a valuable tool for hardware testing, debugging, and security assessments.

Various example implementations are described herein with respect to the accompanying Figures.

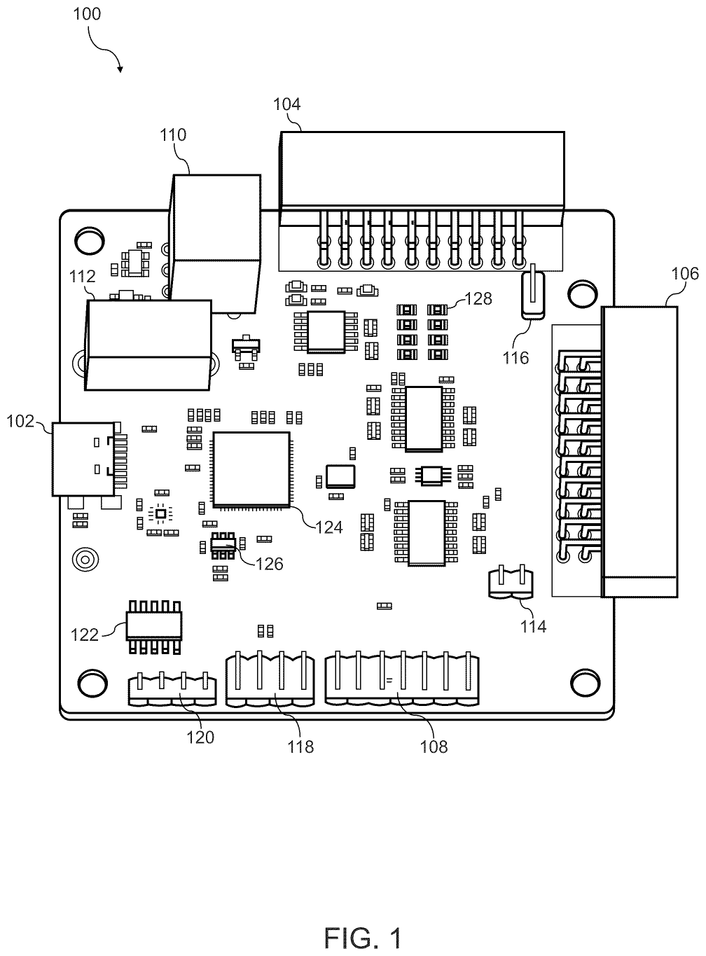

FIG. 1 depicts an example schematic 100 which includes an example embodiment of a multi-protocol board assembly. The example embodiment of the multi-protocol board assembly can include a Universal Serial Bus (USB) to 4-serial channel processor chip 102, three UART ports 104, a J-Link compatible JTAG connector 106, and a logic analyzer connector 108.

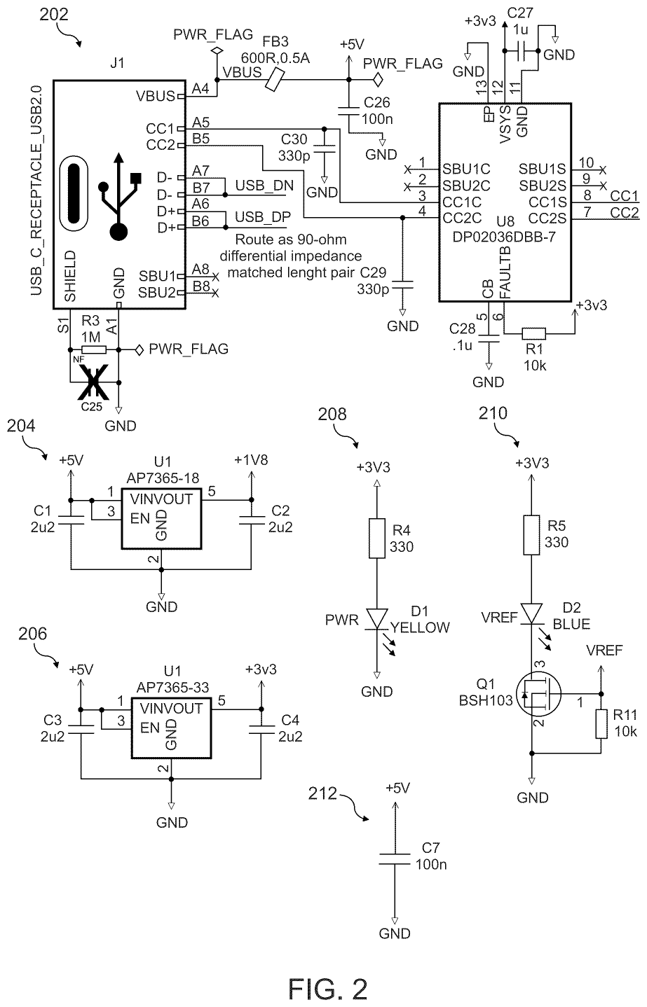

The USB to 4-serial channel processor chip 102 can allow for the multi-protocol board assembly to be connected to a power source, computer, or another computing device. A schematic of the interface between the USB 4-serial channel processor chip 102 is depicted in FIG. 2. For instance, turning to FIG. 2, the USB to 4-serial channel processor chip 202 can interface with connector 204, connector 206, connector 208, connector 210, or connector 212.

The three UART ports 104 can include a first, third, and fourth serial port. The UART ports can be compatible with serial access tools. Serial access tools can include, for example, Putty or screen. The UART ports can be accessed utilizing the serial access tool to access in the same manner as any other USB to serial device.

The UART connector can be a standard 20-pin flat cable connector. The first UART port can have all 7 signal pins connected. The first UART port can be mapped to the first 4233 channel. The second and third UART ports can be mapped to the third and fourth channel ports. The second UART port can be used by the combined JTAG/SWD/I2C and SPI port. The second and third port can have the TX and RX connected. A listing of the pins and respective functions can be as follows: pin 1: VTARGET, pin 2: VTARGET, pin 3: GND, pin 4: TX-C, pin 5: TX-A, pin 6: RX-C, pin 7: RX-A, pin 8: GND, pin 9: RTS-A, pin 10: NC, pin 11: CTS-A, pin 12: RX-D, pin 13: DTR-A, pin 14: VTARGET, pin 15: DSR-A, pin 16: TX-D, pin 17: DCD-A, pin 18: RX-D, pin 19: NC, pin 20: GND.

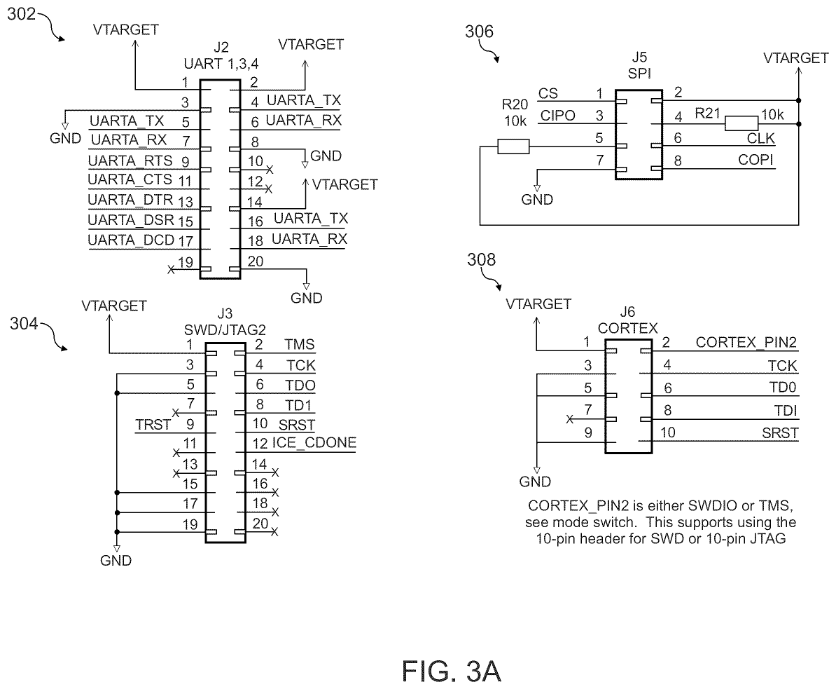

A schematic of the UART ports and other connectors are depicted in FIG. 3A and FIG. 3B. For instance, FIG. 3A can include a J2 jumper 302, a J3 jumper 304, a J5 jumper 306, and a J6 jumper 308. J2 jumper 302 can provide interfaces for the first, third, and fourth UART channel ports. J3 jumper 304 can provide interfaces for the SWD/JTAG ports. J5 jumper 306 can provide interfaces for cortex. FIG. 3B can include a J4 jumper 310, a J8 jumper 312, a J7 jumper 314, a J9 jumper 316, and a ground 318. J4 jumper 310 can provide interfaces for the logic analyzer. J8 jumper 312 can provide for interfaces for iCE40 which can bridge to connect for iCE computing. J7 jumper 314 can provide for interfaces for the I2C channel port. J9 jumper 316 can be removed to target from the reference voltage. By way of example, if the target is self-powered but on-board LDOs are desired for reference voltage.

The J-Link compatible JTAG connector 106 can use any J-Link to XXX connectors or breakouts. The JTAG header can be presented on J3 on the right side of the board opposite the USB to 4-serial channel processor chip 102. The JTAG connector 106 can be a 20-in standard pitch flat cable style. In some instances, the JTAG connector 106 can be matched to the Segger J-LINK pinout as much as possible to allow for compatibility and ease of use with J-Link connectors to make direct connection to an accessible header on a respective target. A listing of the pins and respective functions can be as follows: pin 1: VTARGET, pin 2: NC, pin 3: TRST, pin 4: GND, pin 5: TDI, pin 6: GND, pin 7: TMS, pin 8: GND, pin 9: TCK, pin 10: GND, pin 11: MISC_RX* (connected to BDBUS 6 as an input on the FT4233 or can be NC, pin 12: GND, pin 13: TDO, pin 14: GND, pin 15: SRST, pin 16: GND, pin 17: NC, pin 18: GND, pin 19: NC, pin 20: GND.

A schematic of the J-Link compatible JTAG connector is depicted in FIG. 3A.

The logic analyzer connector 108 can include a 2.54 MM logic analyzer connector. The example 2.54 MM logic analyzer connector can provide for easy connection to most common logic analyzers or a mixed-signal oscilloscope (MSO) scope. Logic analyzer connector 108 can include a 14-pin header at the bottom of the circuit board assembly near the SPI 118 and I2C 120 connectors. This can replicate most of the signal lines to provide for easy connection to a logic analyzer or digital MSO lines of an oscilloscope. In some instances, the 2.54 MM pitch can provide for easy connection using standard Dupont style jumper wires. A listing of the pins and respective functions is as follows: pin 1: CLK, pin 2: COPI/TDI, pin 3: CIPO/TDO/SWDIO, pin 4: TMS/CST, pin 5: TRST, pin 6: SRST, pin 7: TX-A, pin 8: RX-A, pin 9: TX-C, pin 10: RX-C, pin 11: TX-D, pin 12: RX-D, pin 13: GND, pin 14: GND.

The multi-protocol board assembly can additionally include a first switch 110, a second switch 112, J8 jumper 114, J9 jumper 116, SPI 118, I2C 120, cortex 122, power delivery 124, an EEPROM 126, and eight LED indicators 128.

The first switch 110 can include a rotary target voltage select switch. In some implementations, the first switch 110 can include four positions. The first position can match the voltage of a target and rarely be used. For instance, the first position can be utilized when a target has a voltage between 1.6V and 5.5V but incompatible with the provided levels. The first position can adapt if the target changes voltage during a power up process. To make this connection, jumper J9 116 must have a jumper on it. The remaining three positions of the first switch 110 are associated with 1.8V, 3.3V, and 5.5V. In some implementations, the voltage of the remaining three positions can vary. The voltages of the remaining three positions can be determined or otherwise set based on testing the target and determining the proper voltage.

The first switch 110 can function by taking the output of one or more voltage regulators such as U1, U2, or 5V VBUS voltage and sending it to level shifters VREF pin to match the logic levels of these signals. First switch 110 can include four pins. A first pin can function at the voltage of the target, a second pin can function at 1.8V, a third pin can function at 3.3V and a fourth pin can function at 5V.

The second switch 112 can be utilized to combine various inputs to allow the second serial port to be used for JTAG, SPI, SWD, and I2C. When the second switch 112 is in a left position, JTAG and SPI can be facilitated by separating the necessary TX and RX pins. When the second switch 112 is in a right position, the necessary TX and RX pins can be combined to facilitate SWD and I2C.

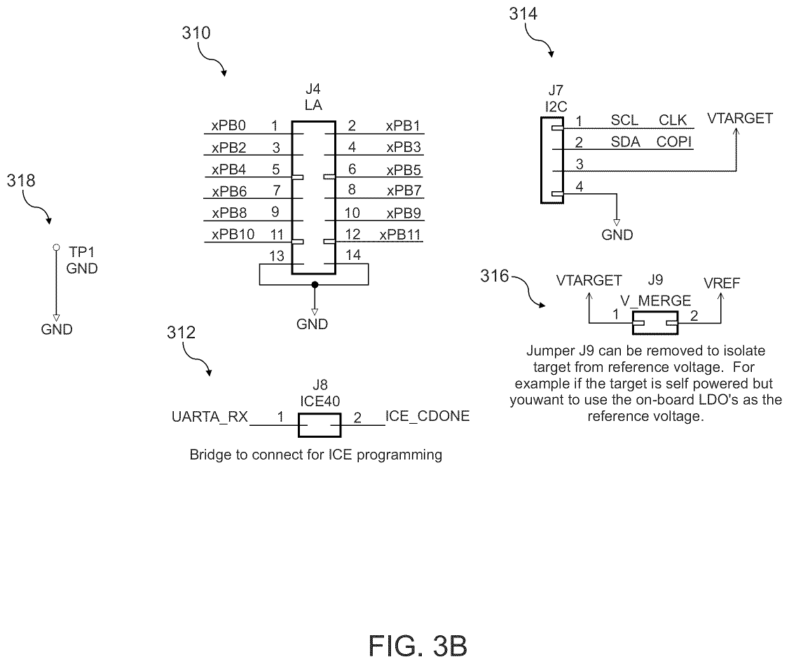

FIG. 4 depicts a schematic of the first switch 402 and the second switch 404.

Jumper J8 114 can connect VREF to VTARGET. This can allow a user to take the voltage level of the target and use that voltage as the voltage level of the level shifters. For this feature to function, jumper J8 114 must have a jumper in place and first switch 110 must be in the first position.

Jumper J9 116 can be utilized for in-circuit emulation field programmable gate array (iCE FPGA) programming. The jumper can be closed to connect UARTA_RX and Misc_RX when second switch 112 is in JTAG mode (e.g., left position).

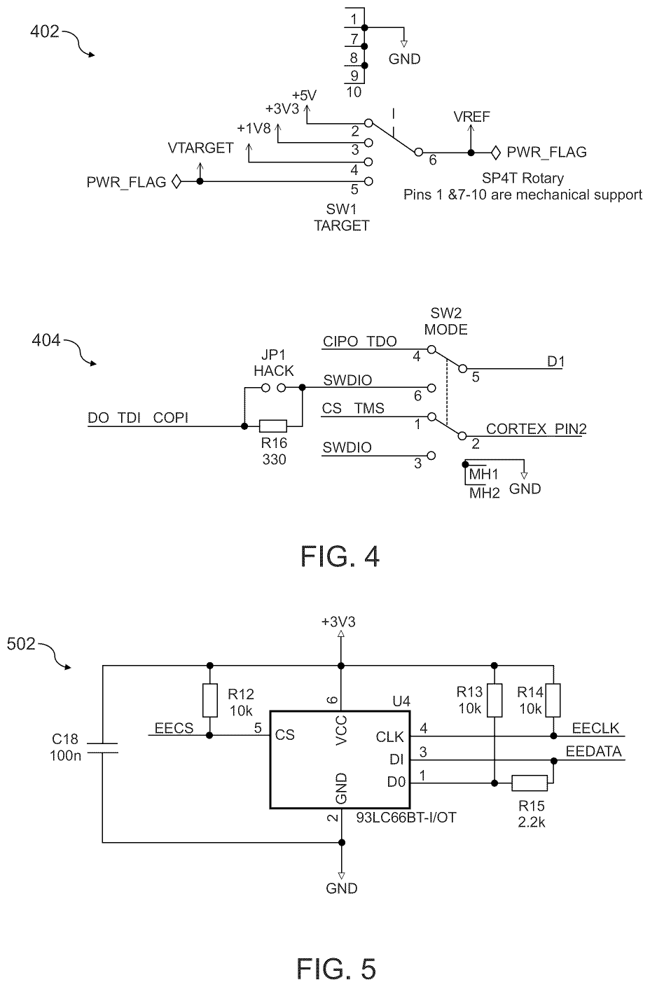

FIG. 5 depicts a schematic of EEPROM 502.

SPI 118 can be active when the second switch 112 is in the left position. SPI 118 can include eight pins. A listing of the pins and respective functions is as follows: pin 1: CS, pin 2: VTARGET, pin 3: CIPO/MISO, pin 4: WP (PULLUP), pin 5: EN (PULLUP), pin 6: CLK, pin 7: GND, pin 8: COPI/MISO.

I2C 120 can be active when the second switch 112 is in the right position. I2C 120 can include four pins. A listing of the pins and respective functions is as follows: pin 1: SCL, pin 2: SDA, pin 3: VTARGET, pin 4: GND.

Cortex 122 can be a 10-pin cortex debug connector. Cortex 122 can enable easy connection to this common debug connector. A listing of the pins and respective functions is as follows: pin 1: VTARGET, pin 2: CORTEX PIN 2, pin 3: GND, pin 4: TCK, pin 5: GND, pin 6: TDO, pin 7: NC, pin 8: TDI, pin 9: GND, pin 10: SRST.

Power delivery 124 can include a FT4233 capable of power delivery. In some implementations, the design can include a DPO2036 for over voltage protection (OVP). The remaining power delivery features can be the default settings of the FTDI. Additional or alternative power delivery designs are possible.

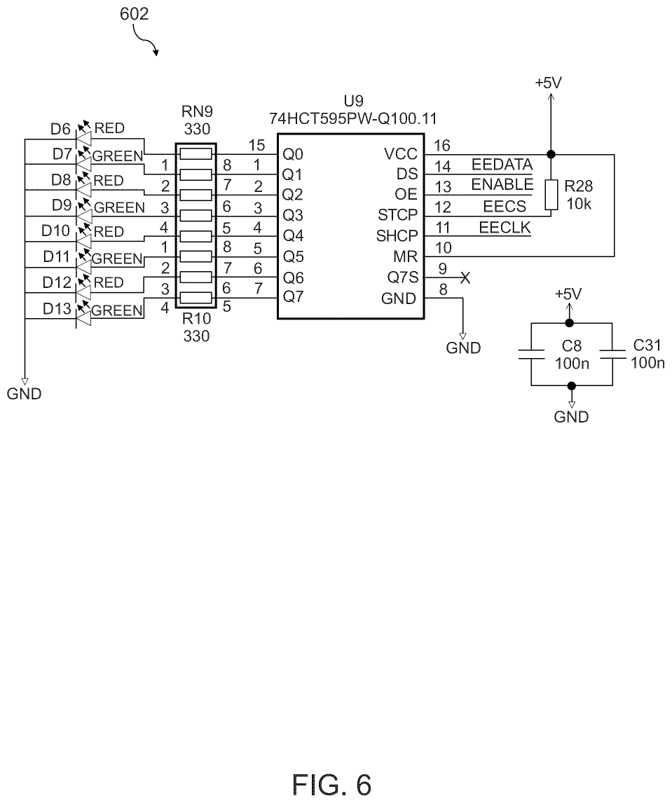

As described herein, the circuit board assembly can include one or more LED indicator lights. FIG. 6 depicts an example schematic of signal indicators 602.

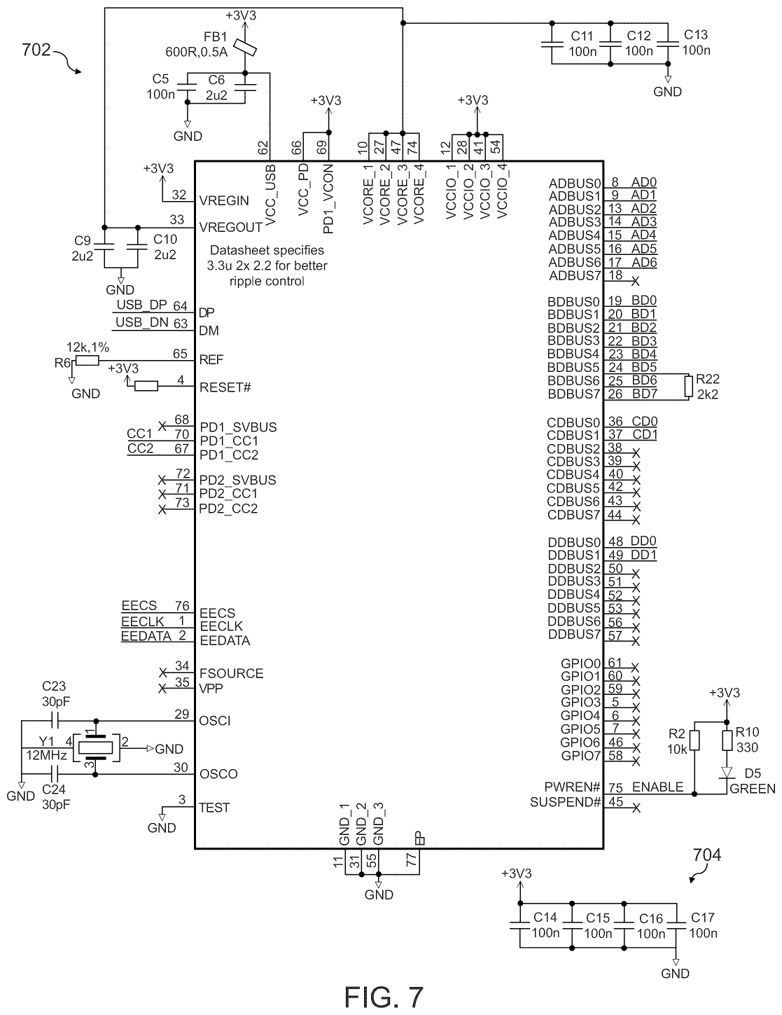

FIG. 7 depicts an example FT4233HPQ 702 and one or more additional capacitors 704 according to example embodiments of the present disclosure.

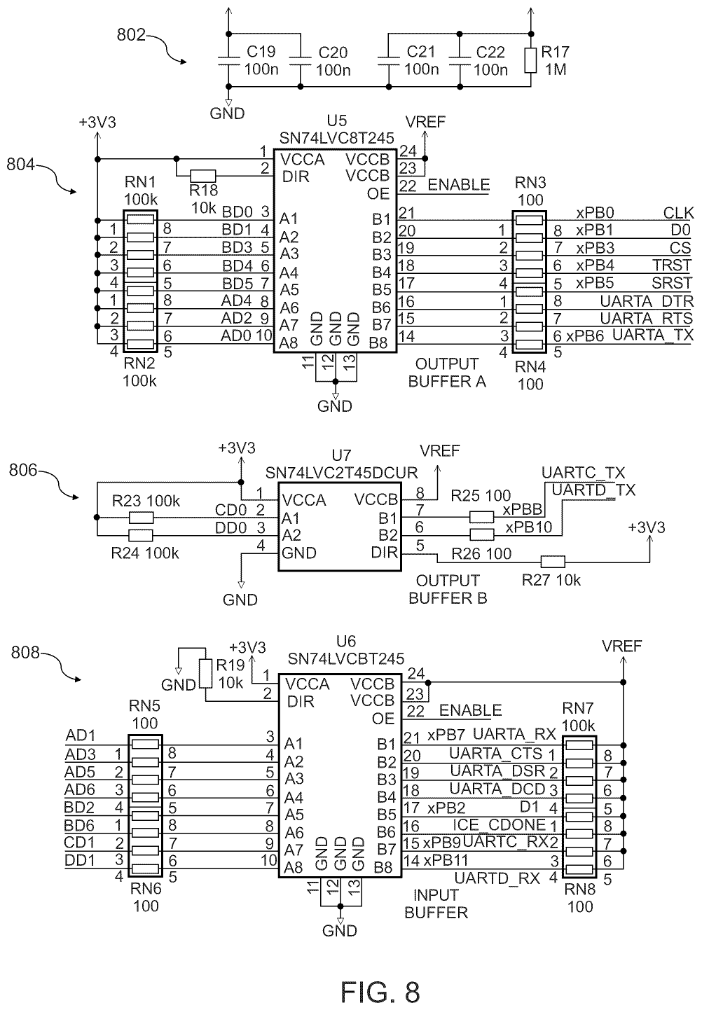

FIG. 8 depicts a first level shifter 802, a second level shifter 804, a third level shifter 806, and a fourth level shifter 808.

In some implementations, the circuit board assembly can include one or more printed circuit boards. By way of example, the respective circuit boards can include a substrate and a number of traces on the substrate. Some of the traces on the substrate can include a solder mask to be conductive traces. The circuit board assembly described herein can include a first and second printed circuit board which can be combined with one or more additional components described herein to create the circuit board assembly.

Aspects of the disclosure have been described in terms of illustrative embodiments thereof. Numerous other embodiments, modifications, or variations within the scope and spirit of the appended claims can occur to persons of ordinary skill in the art from a review of this disclosure. For example, one or ordinary skill in the art can appreciate that the steps depicted or described can be performed in other than the recited order or that one or more illustrated steps can be optional or combined. Any and all features in the following claims can be combined or rearranged in any way possible.

Aspects of the disclosure have been described in terms of illustrative embodiments thereof. Numerous other embodiments, modifications, or variations within the scope and spirit of the appended claims can occur to persons of ordinary skill in the art from a review of this disclosure. Any and all features in the following claims can be combined or rearranged in any way possible. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Lists joined by a particular conjunction such as “or,” for example, can refer to “at least one of” or “any combination of” example elements listed therein, with “or” being understood as “and/or” unless otherwise indicated. Also, terms such as “based on” should be understood as “based at least in part on.”

While the present subject matter has been described in detail with respect to various specific example embodiments thereof, each example is provided by way of explanation, not limitation of the disclosure. Those skilled in the art, upon attaining an understanding of the foregoing, can readily produce alterations to, variations of, or equivalents to such embodiments. Accordingly, the subject disclosure does not preclude inclusion of such modifications, variations, or additions to the present subject matter as would be readily apparent to one of ordinary skill in the art. For instance, features illustrated or described as part of one embodiment can be used with another embodiment to yield a still further embodiment. Thus, it is intended that the present disclosure covers such alterations, variations, or equivalents.

What is claimed is:

1. A multi-protocol board assembly comprising:
a universal serial bus (USB) to 4-serial channel processor chip;
eight light-emitting diode (LED) indicators;
an EEPROM communicatively connected to the USB to 4-serial channel process chip and the eight LED indicators;
a first 20-pin connector connected to a first side of the multi-protocol board assembly; and
a second 20-pin connector connected to a second side of the multi-protocol board assembly wherein the first side of the multi-protocol board assembly is located orthogonal to the second side of the multi-protocol board assembly.

2. The multi-protocol board assembly of claim 1, wherein the 4-serial channels comprise three serial channel ports and one multi-purpose channel port.

3. The multi-protocol board assembly of claim 1, wherein the eight LED indicators comprise:
a first TX LED indicative of transmitting signal by a first serial channel;
a first RX LED indicative of receiving a signal by the first serial channel;
a second TX LED indicative of transmitting a signal by a second serial channel;
a second RX LED indicative of receiving a signal by the second serial channel;
a third TX LED indicative of transmitting a signal by a third serial channel;
a third RX LED indicative of receiving a signal by the third serial channel;
a fourth TX LED indicative of transmitting a signal by a fourth serial channel; and
a fourth RX LED indicative of receiving a signal by the fourth serial channel.

4. The multi-protocol board assembly of claim 1, wherein the first 20-pin connector comprises a universal asynchronous receiver/transmitter.

5. The multi-protocol board assembly of claim 1, wherein the first 20-pin connector comprises three universal asynchronous receiver/transmitter (UART) ports.

6. The multi-protocol board assembly of claim 1, wherein the second 20-pin connector comprises a joint test action group.

7. The multi-protocol board assembly of claim 1, comprising a logic analyzer.

8. The multi-protocol board assembly of claim 7, wherein the logic analyzer comprises a 14-pin 2.54 mm pitch connector.

9. The multi-protocol board assembly of claim 1, comprising a first switch and a second switch.

10. The multi-protocol board assembly of claim 9, wherein the first switch comprises a rotary switch.

11. The multi-protocol board assembly of claim 10, wherein the rotary switch comprises four positions.

12. The multi-protocol board assembly of claim 11, wherein a first position comprises a target voltage, a second position comprises a voltage of 1.8V, a third position comprises a voltage of 3.3V, and a fourth position comprises a voltage of 5.5V.

13. The multi-protocol board assembly of claim 9, wherein the second switch comprises a level shifter.

14. The multi-protocol board assembly of claim 13, wherein the level shifter comprises a first position and a second position.

15. The multi-protocol board assembly of claim 14, wherein the first position of the second switch comprises separating a first TX pin and a first RX pin.

16. The multi-protocol board assembly of claim 15, wherein the first position enables at least one of joint test action group (JTAG) or serial peripheral interface (SPI).

17. The multi-protocol board assembly of claim 14, wherein the second position of the second switch comprises connecting a first TX pin and a first RX pin.

18. The multi-protocol board assembly of claim 17, wherein the second position enables at least one of serial wire debug (SWD) or inter-integrated circuit (I2C).

19. A method for manufacturing a multi-protocol board assembly comprising:
obtaining a printed circuit board;
attaching a universal serial bus (USB) to 4-serial channel processor chip to the printed circuit board;
attaching eight light-emitting diode (LED) indicators to the printed circuit board;
attaching an EEPROM communicatively connected to the USB to 4-serial channel process chip and the eight LED indicators to the printed circuit board;
attaching a first 20-pin connector connected to a first side of the multi-protocol board assembly to the printed circuit board; and
attaching a second 20-pin connector connected to a second side of the multi-protocol board assembly wherein the first side of the multi-protocol board assembly is located orthogonal to the second side of the multi-protocol board assembly to the printed circuit board.

20. A method for interfacing multiple hardware devices via a multi-protocol board assembly comprising:
obtaining a multi-protocol board assembly comprising:
a universal serial bus (USB) to 4-serial channel processor chip;
eight light-emitting diode (LED) indicators;
an EEPROM communicatively connected to the USB to 4-serial channel process chip and the eight LED indicators;
a first 20-pin connector connected to a first side of the multi-protocol board assembly; and
a second 20-pin connector connected to a second side of the multi-protocol board assembly wherein the first side of the multi-protocol board assembly is located orthogonal to the second side of the multi-protocol board assembly; and
connecting one or more hardware devices to the multi-protocol board assembly via at least one of the first 20-pin connector or the second 20-pin connector.
